(19) United States
(12) Patent Application Publication
(10) Pub. No.: US 2025/0249487 A1
(43) Pub. Date: Aug. 7, 2025

(54) METHOD OF PROCESSING SUBSTRATE AND METHOD OF MANUFACTURING SEMICONDUCTOR DEVICES USING THE SAME

(71) Applicant: Samsung Electronics Co., Ltd., Suwon-si (KR)

(72) Inventors: Jihoon JEONG, Suwon-si (KR); Taeheon KIM, Suwon-si (KR); Junho YOON, Suwon-si (KR); Jongwon LEE, Suwon-si (KR); Junho LEE, Suwon-si (KR); Jiwoong JUNG, Suwon-si (KR); Jeonghwa HONG, Suwon-si (KR); Younghoo KIM, Suwon-si (KR); Woogwan SHIM, Suwon-si (KR)

(73) Assignee: Samsung Electronics Co., Ltd., Suwon-si (KR)

(21) Appl. No.: 18/912,995

(22) Filed: Oct. 11, 2024

(30) Foreign Application Priority Data
Feb. 2, 2024 (KR) 10-2024-0016818

(51) Int. Cl. B08B 3/08; B08B 7/00; H01L 21/02

(52) U.S. Cl. CPC B08B 3/08; B08B 7/0021; H01L 21/02057

(57) ABSTRACT

A method of processing a substrate includes supplying an organic solvent to the substrate, transferring the substrate to a processing space in a chamber, supplying fluid to the processing space of the chamber and pressurizing the processing space, maintaining pressure in the processing space of the chamber for a period of time subsequently to pressurizing the processing space, and depressurizing the processing space of the chamber subsequently to maintaining the pressure in the processing space. The pressurizing the processing space of the chamber includes causing the pressure in the processing space to increase in each of a first pressurization period, a second pressurization period, and a third pressurization period that are successive. A pressure increase rate in the second pressurization period is greater than a pressure increase rate in the third pressurization period.

### CROSS-REFERENCE TO RELATED APPLICATION

This application claims benefit of priority to Korean Patent Application No. 10-2024-0016818 filed on Feb. 2, 2024 in the Korean Intellectual Property Office, the disclosure of which is incorporated herein by reference in its entirety.

### BACKGROUND

The present inventive concepts relate to methods of processing a substrate and methods of manufacturing a semiconductor device using the same.

During a semiconductor device manufacturing process, various processes, such as photolithography, etching, ashing, ion implantation, deposition, and cleaning, are performed. The photolithography process includes application, exposure, and development processes. In the photolithography process, a photoresist is applied on a substrate, a circuit pattern is exposed on the substrate on which a photoresist film is formed, and an exposed region of the substrate is selectively developed. Thereafter, a cleaning process and a drying process are performed in which a developer used in the development process is removed from the substrate. In the cleaning and drying processes, technology is required to prevent the collapse of patterns with a fine width or a fine spacing on the substrate.

### SUMMARY

Some example embodiments of the present inventive concepts provide a method of processing a substrate including a pressing process including sections with different pressure increase rates.

According to some example embodiments of the present inventive concepts, a method of processing a substrate may include supplying an organic solvent to the substrate, transferring the substrate to a processing space in a chamber, supplying fluid to the processing space of the chamber and pressurizing the processing space, maintaining pressure in the processing space of the chamber for a period of time subsequently to pressurizing the processing space, and depressurizing the processing space of the chamber subsequently to maintaining the pressure in the processing space. The pressurizing the processing space of the chamber may include causing the pressure in the processing space to increase in each of a first pressurization period, a second pressurization period, and a third pressurization period that are successive. A pressure increase rate in the second pressurization period may be greater than a pressure increase rate in the third pressurization period.

According to some example embodiments of the present inventive concepts, a method of processing a substrate may include pressurizing a processing space of a chamber in which the substrate is located based on supplying fluid to a lower portion of the substrate in the processing space of the chamber through a lower supply line, maintaining pressure in the processing space of the chamber for a period of time subsequently to pressurizing the processing space, and depressurizing the processing space subsequently to maintaining the pressure in the processing space based on discharging the fluid through a lower discharge line. The pressurizing the processing space may include causing the pressure in the processing space to increase in each of a first pressurization period, a second pressurization period, and a third pressurization period that are successive. A pressure increase rate in the second pressurization period may be greater than a pressure increase rate in the third pressurization period. The depressurizing the processing space may include causing the pressure in the processing space to decrease in each of a first depressurization period and a second depressurization period. The depressurizing the processing space may include supplying additional fluid to the processing space of the chamber through an upper supply line in the first depressurization period.

According to some example embodiments of the present inventive concepts, a method of manufacturing a semiconductor device may include forming a pattern on a substrate, performing a cleaning process on the substrate, transferring the substrate to a processing space in a chamber, performing a drying process on the substrate within the chamber, and removing the substrate from the chamber. The cleaning process may include supplying an organic solvent to the substrate. The drying process may include supplying fluid to the processing space of the chamber and pressurizing the processing space, maintaining pressure in the processing space of the chamber for a period of time subsequently to pressurizing the processing space, and depressurizing the processing space of the chamber subsequently to maintaining the pressure in the processing space. Pressurizing the processing space of the chamber may include causing the pressure in the processing space to increase in each of a first pressurization period, a second pressurization period, and a third pressurization period that are successive. A pressure increase rate in the second pressurization period may be greater than a pressure increase rate in the third pressurization period. The pressurizing the processing space may include supplying the fluid to a lower portion of the substrate through a lower supply line. A temperature of the fluid supplied to the processing space may be 40° C. to 90° C. The fluid may include at least one of carbon dioxide (CO₂), nitrogen (N₂), nitrous oxide (N₂O), hexafluoroethane (C₂F₆), or sulfur hexafluoride (SF₆).

### BRIEF DESCRIPTION OF THE DRAWINGS

The above and other aspects, features, and advantages of the present inventive concepts will be more clearly understood from the following detailed description, taken in conjunction with the accompanying drawings, in which:

FIG. 1 is a diagram illustrating a substrate processing system including a substrate processing device according to some example embodiments;

FIG. 2 is a diagram illustrating a structure of a substrate processing device according to some example embodiments;

FIG. 3 is a diagram illustrating a substrate processing system including a supply module and a substrate processing device according to some example embodiments;

FIG. 4 is a phase diagram of an organic solvent and a fluid according to some example embodiments;

FIG. 5 is a flowchart of a method of processing a substrate according to some example embodiments;

FIG. 6 illustrates pressure changes over time in a processing space within a chamber according to some example embodiments;

FIGS. 7, 8, 9, 10, 11, and 12 are schematic diagrams illustrating a process sequence of a drying process according to some example embodiments;

FIG. 13 illustrates pressure changes over time in a processing space within a chamber according to some example embodiments of the present inventive concepts and a comparative example; and

FIG. 14 is a schematic diagram illustrating a drying process according to a comparative example.

### DETAILED DESCRIPTION

Hereinafter, example embodiments of the present inventive concepts are described with reference to the accompanying drawings.

In order to clearly explain the present inventive concepts in the drawings, parts that are not related to the description are omitted, and similar parts are given similar reference numerals throughout the specification. In the flowchart described with reference to the drawings, the order of operations may be changed, several operations may be merged, certain operations may be divided, and certain operations may not be performed.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof may be recited herein as being “identical”, “the same”, or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

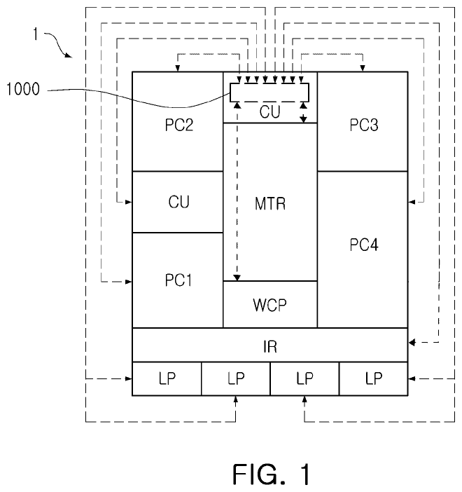

FIG. 1 is a diagram illustrating a substrate processing system 1 including a substrate processing device according to some example embodiments.

Referring to FIG. 1, the substrate processing system 1 may include a plurality of load ports LP, an index robot IR, a cooling processing module WCP, a transfer robot MTR, one or more control units CU, and a plurality of process modules PC1 to PC4 etc.

A carrier accommodating a substrate W may be disposed in the load port LP. A front opening unified pod (FOUP) may be used as the carrier, but is not limited thereto. The carrier may be carried in from the outside to the load port LP or carried out of the load port LP by overhead transfer (OHT), which may include a gantry, rail and mover device configured to move on said rail, or the like.

Here, the substrate W may be covered with an exposed photosensitive film. For example, the photosensitive film may be a negative photosensitive film (i.e., negative tone develop (NTD)) or a positive photosensitive film (i.e., positive tone develop (PTD)) or may be a chemically amplified photosensitive film (i.e., chemically amplified resist (CAR)) or a non-chemically amplified photosensitive film (i.e., non-chemically amplified resist (Non-CAR)).

The index robot IR may transfer the substrate W between the carrier disposed at the load port LP and the cooling processing module WCP. The index robot IR may be disposed on a rail and may move in a direction in which the plurality of load ports LP are arranged.

The cooling processing module WCP may be a space in which the substrate W temporarily resides between the load port LP and the process modules PC1 to PC4. In addition, the cooling processing module WCP may adjust the temperature of the substrate W. That is, the cooling processing module WCP may adjust a temperature of the substrate W transferred by the index robot IR or a temperature of the substrate W processed by the process modules PC1 to PC4 to a preset value.

The transfer robot MTR may retrieve the substrate W disposed on the cooling processing module WCP and transfer the retrieved substrate W to a preset process module (e.g., PC1) among the plurality of process modules PC1 to PC4. In addition, the transfer robot MTR may transfer the substrate W from any one process module (e.g., PC1) among the plurality of process modules PC1 to PC4 to another process module (e.g., PC2).

The plurality of process modules PC1 to PC4 may be arranged in a row, may be stacked up and down, or may be combined to be disposed. As shown, some process modules PC1 and PC2 and some other process modules PC3 and PC4 may be disposed on both sides (e.g., opposite sides) of the transfer robot MTR. The arrangement of the plurality of process modules PC1 to PC4 is not limited to the aforementioned example and may be changed considering the footprint or process efficiency of the substrate processing device.

For example, the process module PC1 may be a development chamber, which is a region in which the substrate W on which the exposed photosensitive film is formed is developed with a developer (e.g., n-butyl acetate (nBA)). When n-butylacetate is used as a developer, the photosensitive film may be an NTD.

At least one of the process modules PC2, PC3, or PC4 may be a cleaning chamber. In the cleaning chamber, a cleaning process may be performed in which a chemical solution, a rinse solution, and an organic solvent are sequentially supplied to the substrate W.

At least one of the process modules PC2, PC3, or PC4 may be a supercritical processing chamber (or high-pressure fluid processing chamber). The substrate W on which the cleaning process has been performed may be transferred to a supercritical processing chamber. In the supercritical processing chamber, a drying process may be performed to remove a (wetted) developer solution remaining on the substrate W developed in the process module PC1 using a supercritical fluid. The supercritical fluid may be, but is not limited to, carbon dioxide. The supercritical fluid in use may vary depending on the type of remaining developer.

At least one of the process modules PC2, PC3, or PC4 may be a bake chamber, and a process of hard baking the substrate W from which the developer has been removed in the process module (PC2 or PC3) may be performed.

The control unit CU may generally control the operations of the index robot IR, cooling processing module WCP, transfer robot MTR, and the plurality of process modules PC1 to PC4. The control unit CU may include, may be included in, and/or may be configured to implement a control device 1000 as described herein which may be connected to and configured to control each of the index robot IR, cooling processing module WCP, transfer robot MTR, the plurality of process modules PC1 to PC4, and the load ports LP (for example based on being configured to transmit electrical signals and/or control signals thereto).

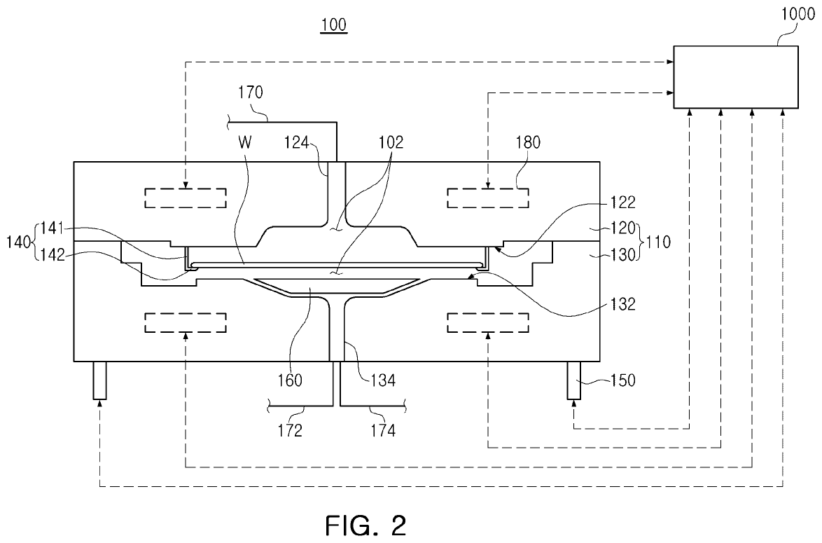

FIG. 2 is a diagram illustrating a structure of a substrate processing device. For example, the substrate processing device of FIG. 2 may include the supercritical processing chamber described above with reference to FIG. 1.

Referring to FIG. 2, the substrate processing device 100 may include a chamber 110, a substrate supporter 140, an upper supply port 124, a lower supply port 134, a lower discharge port, and a blocking member 160. The substrate processing device 100 may further include a lifting cylinder 150 disposed below the chamber 110.

In some example embodiments, the substrate processing device 100 may be a device for processing the substrate W using a supercritical fluid. For example, the substrate processing device 100 may perform a drying process in which an organic solvent on the substrate W is diluted or substituted with a supercritical fluid and then discharged.

The organic solvent may be, for example, an isopropyl alcohol (IPA) solution. The supercritical fluid may be a substance having a gas-like diffusivity, viscosity, and surface tension, having liquid-like solubility, and having a temperature and pressure above a critical point. For example, the supercritical fluid may include at least one of carbon dioxide (CO₂), nitrogen (N₂), nitrous oxide (N₂O), water (H₂O), methane (CH₄), ethane (C₂H₆), propane (C₃H₈), ethylene (C₂H₄), propylene (C₃H₆), methanol (CH₃OH), ethanol (C₂H₅OH), hexafluoroethane (C₂F₆), sulfur hexafluoride (SF₆), acetone (C₃H₆O), any combination thereof, or the like. In some example embodiments, the supercritical fluid may include at least one of carbon dioxide (CO₂), nitrogen (N₂), nitrous oxide (N₂O), hexafluoroethane (C₂F₆), or sulfur hexafluoride (SF₆). In some example embodiments, the supercritical fluid may include carbon dioxide (CO₂).

Supercritical fluid refers to a state of matter existing under conditions above a critical temperature and critical pressure at which liquid and gas are distinguished from each other. In some example embodiments, when the supercritical fluid is supercritical carbon dioxide (CO₂), the critical pressure of the supercritical carbon dioxide (CO₂) may be about 73.8 bar, and the critical temperature of the supercritical carbon dioxide (CO₂) may be about 31° C. Accordingly, when the supercritical fluid is supercritical carbon dioxide (CO₂), the supercritical fluid may be at a pressure that is equal to or greater than about 73.8 bar and a temperature that is equal to or greater than about 31° C.

The chamber 110 may correspond to the supercritical processing chamber described above with reference to FIG. 1. The chamber 110 may include an upper chamber 120 and a lower chamber 130. The upper chamber 120 and the lower chamber 130 may define a processing space 102 therebetween, and the substrate supporter 140 and the substrate W are disposed in the processing space 102. A substrate processing process, such as a drying process, may be performed in the processing space 102. For example, the upper chamber 120 may include a lower surface 122 and the lower chamber 130 may include an upper surface 132. The lower surface 122 of the upper chamber 120 and the upper surface 132 of the lower chamber 130 may be provided as upper and lower walls of the processing space 102, respectively.

The lower chamber 130 may be provided to be raised and lowered with respect to the upper chamber 120. For example, the lifting cylinder 150 disposed below the lower chamber 130 may generate a driving force in a vertical direction. The lifting cylinder 150 may seal the processing space 102 from the outside by bringing the lower chamber 130 into close contact with the upper chamber 120 while the substrate processing process is performed. Although not shown, the substrate processing device 100 may further include a lifting rod disposed between the upper chamber 120 and the lower chamber 130. The lifting rod may generate a driving force in the vertical direction to bring the lower chamber 130 into close contact with the upper chamber 120.

The lifting cylinder 150 and the lifting rod may also generate downwardly driving force to space the lower chamber 130 from the upper chamber 120. When the lower chamber 130 is spaced apart from the upper chamber 120, the processing space 102 may be opened, and the substrate W may be carried into or carried out of the processing space 102.

In some example embodiments, the upper chamber 120 may include the upper supply port 124. The upper supply port 124 may vertically penetrate through the upper chamber 120 and communicate with the processing space 102. In some example embodiments, lower chamber 130 may include the lower supply port 134. The lower supply port 134 may vertically penetrate through the lower chamber 130 and communicate with the processing space 102. In some example embodiments, the supercritical fluid may be supplied to the processing space 102 through the upper supply port 124 or the lower supply port 134. Although not shown, the lower chamber 130 may further include a lower discharge port. In some example embodiments, the organic solvent and supercritical fluid may be discharged from the processing space 102 through the lower discharge port.

The substrate supporter 140 may be located in the processing space 102 of the chamber 110 and may support the substrate W. The substrate supporter 140 may be coupled to the upper chamber 120 and may include a vertical portion 141 and a horizontal portion 142.

The vertical portion 141 may extend downwardly from a lower surface of the upper chamber 120. A lower end of the vertical portion 141 may be vertically coupled to the horizontal portion 142. The horizontal portion 142 may extend from the lower end of the vertical portion 141 to the inside of the processing space 102 of the chamber 110. The substrate W may be disposed on the horizontal portion 142. The horizontal portion 142 may support a lower surface of an edge region of the substrate W.

The blocking member 160 may be disposed between the upper surface 132 of the lower chamber 130 and the substrate W. The blocking member 160 may be installed to be spaced apart from the upper surface 132 of the lower chamber 130 by a preset distance. The blocking member 160 may be fixed on the upper surface 132 of the lower chamber 130 by a support rod (not shown). The blocking member 160 may include a plate having a certain thickness occupying a certain space within the processing space 102. The blocking member 160 may prevent the supercritical fluid from being directly sprayed onto the lower surface of the substrate W from the lower supply port 134.

In some example embodiments, the substrate processing device 100 may be connected to an upper supply line 170, a lower supply line 172, and a lower discharge line 174. The upper supply line 170 may communicate with the upper supply port 124, and the lower supply line 172 may communicate with the lower supply port 134. The lower discharge line 174 may communicate with the lower discharge port. A line may be referred to herein interchangeably as a conduit, pipe, tube, or the like.

In some example embodiments, the substrate processing device 100 may further include one or more heaters 180 disposed in at least one of the upper chamber 120 and the lower chamber 130. The one or more heaters 180 may, for example, be an electrically resistive heater. The one or more heaters 180 may, for example, heat the inside of the chamber 110 so that the supercritical fluid supplied to the processing space 102 is maintained above a critical temperature.

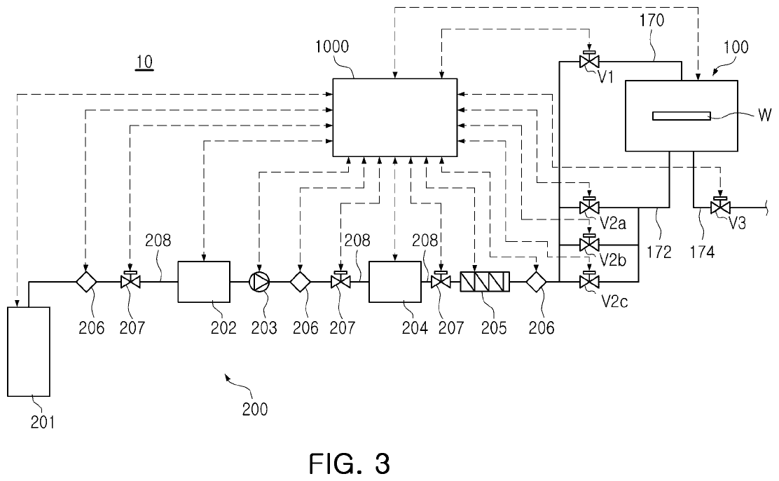

FIG. 3 is a diagram illustrating a substrate processing system including a supply module and a substrate processing device according to some example embodiments.

Referring to FIG. 3, the substrate processing system 10 may include a substrate processing device 100 and a supply module 200 connected to the substrate processing device 100. The substrate processing device 100 may have the same structure as the substrate processing device 100 described above with reference to FIG. 2.

The supply module 200 may be connected to the substrate processing device 100 and may supply supercritical fluid to the substrate processing device 100. The supply module 200 may include a fluid storage tank 201, a condenser 202, a pump 203 for a module (or a module pump 203), a reservoir tank 204, a heater 205, a filter 206, and a valve 207 for a module (or a module valve 207), and a line 208.

The fluid storage tank 201 has an internal space and stores a low-temperature fluid therein. In some example embodiments, the fluid stored in the fluid storage tank 201 may be carbon dioxide (CO₂).

The condenser 202 may be connected to the fluid storage tank 201 to pressurize the supplied fluid. That is, the condenser 202 may be connected to the fluid storage tank 201 through the line 208 and may pressurize the fluid supplied from the fluid storage tank 201.

The module pump 203 may be disposed at the rear of the condenser 202 and may be connected to the condenser 202 through the line 208. The module pump 203 may serve to provide driving force to supply fluid to the substrate processing device 100. In addition, the module pump 203 may serve to pressurize the fluid supplied to the substrate processing device 100 so that the fluid is converted into supercritical fluid.

The reservoir tank 204 is disposed at the rear of the module pump 203 and may be connected to the module pump 203 through the line 208. The reservoir tank 204 may serve to mix the fluid that has passed through the condenser 202 and then supply the mixed fluid to the substrate processing device 100. To this end, the reservoir tank 204 may have an internal space in which the fluid passing through the condenser 202 may be sufficiently mixed.

The heater 205 may be connected to the reservoir tank 204 through the line 208 and may serve to heat the fluid supplied from the reservoir tank 204. Accordingly, fluid heated through the heater 205 may be supplied to the substrate processing device 100.

A plurality of filters 206 may be installed in the line 208. The filters 206 serve to remove foreign substances from the fluid supplied to the substrate processing device 100 and ensure that pure fluid from which the foreign substances have been removed is supplied to the substrate processing device 100. As an example, the filters 206 may be installed in the line 208 to be disposed at the rear of the fluid storage tank 201, the module pump 203, and the heater 205.

The module valves 207 are installed in the line 208 and may be provided in plural. As an example, the module valves 207 may be disposed between the fluid storage tank 201 and the condenser 202, between the module pump 203 and the reservoir tank 204, between the reservoir tank 204 and the heater 205, and between the heater 205 and the substrate processing device 100. However, the present inventive concepts are not limited thereto, and one or more module valves 207 may be added or omitted as needed.

In this manner, as the fluid supplied from the fluid storage tank 201 passes through the condenser 202, reservoir tank 204, and heater 205, the fluid may be changed into a high-temperature, high-pressure fluid and supplied to the substrate processing device 100.

The substrate processing device 100 may be connected to an upper supply line 170, a lower supply line 172, and a lower discharge line 174. The upper supply line 170 and lower supply line 172 may be connected to the supply module 200. For example, the upper supply line 170 and the lower supply line 172 may be connected to the reservoir tank 204 through the line 208. The reservoir tank 204 may supply fluid to the substrate processing device 100 through the upper supply line 170 or the lower supply line 172.

In some example embodiments, the substrate processing system 10 may include an upper valve V1 disposed between the upper supply line 170 and the supply module 200 and a first lower valve V2a, a second lower valve V2b, and a third lower valve V2c disposed between the lower supply line 172 and the supply module 200. The substrate processing system 10 may further include a discharge valve V3 connected to the lower discharge line 174. Here, the first lower valve V2a, the second lower valve V2b, and the third lower valve V2c may be collectively referred to as ‘lower valves’. The upper valve V1 and lower valves V2a, V2b, and V2c may be collectively referred to as ‘pressure control valves’.

In some example embodiments, the pressure control valves may be connected in parallel between the supply module 200 and the substrate processing device 100. In some example embodiments, the pressure control valves may be selectively controlled. For example, only one of the pressure control valves may be opened to allow fluid to be supplied to the substrate processing device 100. When a plurality of pressure control valves are installed, only some of the valves may be opened to provide supercritical fluid at an initial low flow rate/low pressure, and the number of opened valves may be increased over time to control pressure of the provided supercritical fluid.

In some example embodiments, the first lower valve V2a, the second lower valve V2b, and the third lower valve V2c may have different controllable pressure levels. For example, the second lower valve V2b may control a greater pressure than the first lower valve V2a, and the third lower valve V2c may control a greater pressure than the second lower valve V2b.

However, the present example embodiments are not limited thereto. The arrangement structure of the pressure control valve illustrated in FIG. 3 is an example and the number (quantity), position, and characteristics of the valves may vary according to some example embodiments. In some example embodiments, a single lower valve may be connected to the lower supply line 172, and in order to provide supercritical fluid at an initial low flow rate/low pressure, only a portion of the valve may be opened, and by expanding an opened surface over time, a determined increased amount of supercritical fluid may be provided. In this case, the lower valve may be provided as a mass flow controller (MFC) that may be minutely controlled for the degree of opening of the valve.

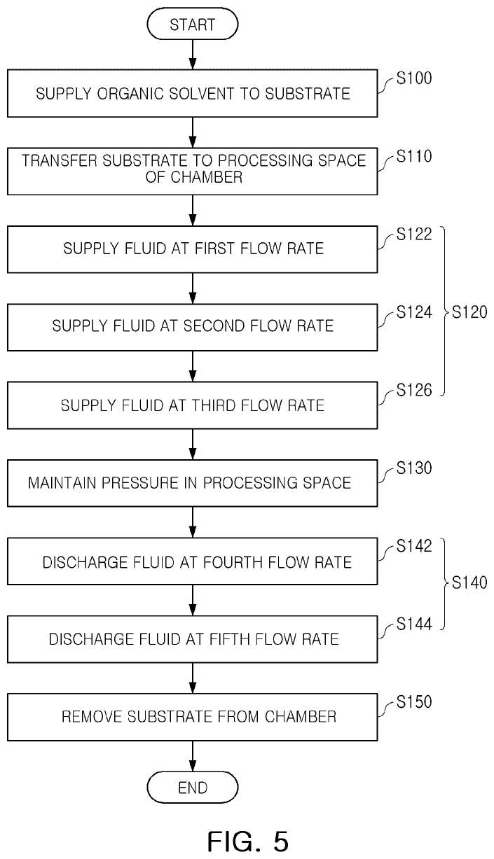

Referring to FIGS. 1, 2, and 3, the substrate processing system 1, the substrate processing device 100, and/or the substrate processing system 10 may include a control device 1000. In some example embodiments, some or all of the substrate processing system 1, the substrate processing device 100, the substrate processing system 10, and/or any portions thereof (e.g., the fluid storage tank 201, the condenser 202, the module pump 203, the reservoir tank 204, the heater 205, any of the filters 206, any of the valves 207, V1, V2a, V2b, V2c, and/or V3, any portions of the substrate processing device 100 including any heaters 180, lifting cylinders 150 and/or any drivers mechanically coupled thereto, or the like) may be connected (e.g., electrically and/or communicatively coupled) to the control device 1000. The control device 1000 may be configured to control operations of some or all of the substrate processing system 1, the substrate processing device 100, the substrate processing system 10, and/or any portions thereof (e.g., the fluid storage tank 201, the condenser 202, the module pump 203, the reservoir tank 204, the heater 205, any of the filters 206, any of the module valves 207, V1, V2a, V2b, V2c, and/or V3, any portions of the substrate processing device 100 including any heaters 180, lifting cylinders 150 and/or any drivers mechanically coupled thereto, or the like), for example based on transmitting control signals, electrical signals, or the like thereto to cause the substrate processing system 1, the substrate processing device 100, the substrate processing system 10, and/or any portions thereof to implement one or more operations of one or more methods according to some example embodiments, including performing one or more (or all) operations of a method of manufacturing a semiconductor device, a method of processing a substrate W in a processing space 102 of a chamber of a substrate processing device 100, any combination thereof, or the like, including any or all of the operations of the method shown in FIG. 5.

As described herein, any devices, systems, modules, portions, units, controllers, circuits, and/or portions thereof according to any of the example embodiments, and/or any portions thereof (including, without limitation, the control device 1000, the substrate processing system 1, the substrate processing device 100, the substrate processing system 10, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a computer readable storage device (e.g., a memory) storing a program of instructions, for example a solid state drive (SSD), for example a non-transitory computer readable storage device, and the processing circuitry may further include a processor (e.g., CPU) configured to execute the program of instructions to implement the functionality and/or methods performed by some or all of any devices, systems, modules, portions, units, controllers, circuits, and/or portions thereof according to any of the example embodiments, for example causing the substrate processing system 1, the substrate processing device 100, the substrate processing system 10, any portion thereof, or the like to perform some or all of the operations of the methods according to some or all of the example embodiments, including one or more (or all) operations of a method of manufacturing a semiconductor device, a method of processing a substrate W in a processing space 102 of a chamber of a substrate processing device 100, or the like, including any or all of the operations of the method shown in FIG. 5.

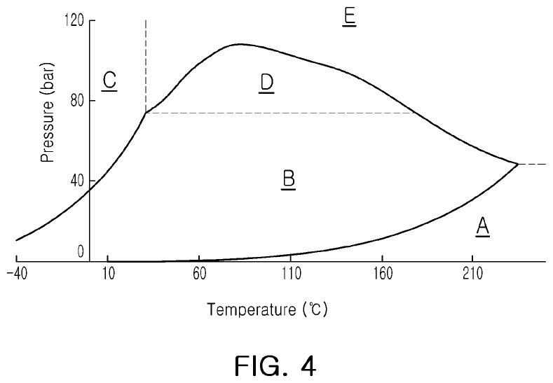

FIG. 4 is a phase diagram of an organic solvent and a fluid. FIG. 4 is a diagram illustrating a change in phase of an organic solvent and fluid according to temperature and pressure.

Referring to FIG. 4, in region A, both the organic solvent and fluid may be in a gaseous state. In region B, the organic solvent may be in a liquid state and the fluid may be in a gaseous state. In region C, both the organic solvent and the fluid may be in a liquid state. In region D, the organic solvent may be in a liquid state and the fluid may be in a supercritical state. In region E, both the organic solvent and the fluid may be in a supercritical state. In region E, the organic solvent and fluid may be completely mixed to form a mixed phase.

In some example embodiments of the present inventive concepts, a method of processing a substrate may adjust the pressure within the processing space 102 by supplying or discharging a fluid having a constant temperature into the processing space 102, and the organic solvent or fluid may change in phase according to the pressure within the processing space 102. In some example embodiments, a temperature of the fluid supplied to the processing space 102 and a temperature inside the processing space 102 may be between about 40° C. and about 90° C.

Next, a method of processing a substrate and a method of manufacturing a semiconductor device using the same according to some example embodiments are described.

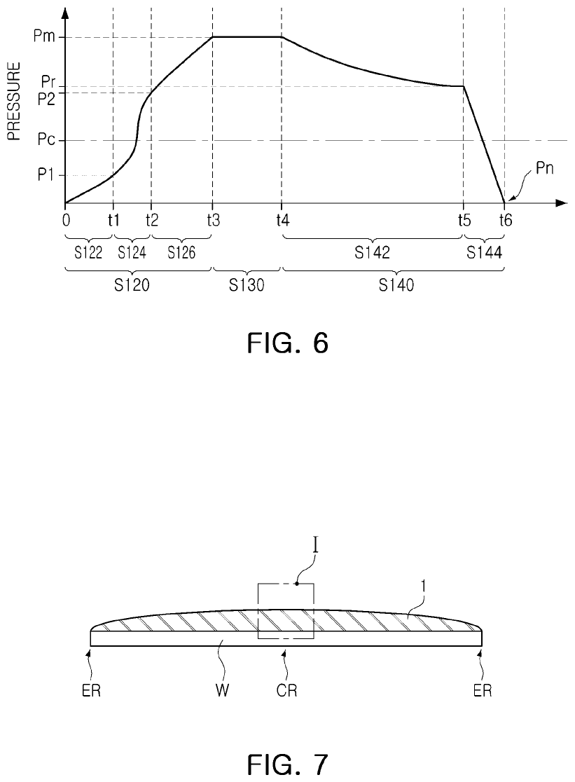

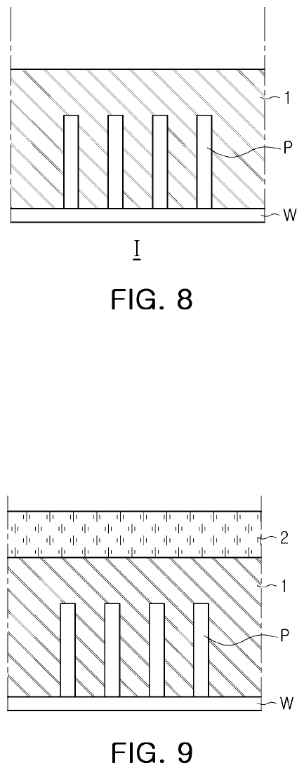

FIG. 5 is a flowchart of a method of processing a substrate according to some example embodiments. FIG. 6 illustrates pressure changes over time in a processing space within a chamber according to some example embodiments. FIGS. 7, 8, 9, 10, 11, and 12 are schematic diagrams illustrating a process sequence of a drying process according to some example embodiments. FIG. 8 is a partially enlarged view of FIG. 7 and may correspond to region I. The method shown in FIG. 5 may be implemented based on a control device, such as control device 1000, controlling operations of one or more portions of the substrate processing system 1, the substrate processing device 100, the substrate processing system 10, any portion thereof, or the like (e.g., based on executing a program of instructions stored in a memory of the control device 1000 to transmit one or more control signals, electrical signals, etc. to one or more portions of the substrate processing system 1, the substrate processing device 100, the substrate processing system 10, any portion thereof, or the like).

Referring to FIG. 5, the method of processing a substrate according to some example embodiments may include supplying an organic solvent to a substrate (S100), transferring the substrate to a processing space of a chamber (S110), pressurizing the processing space (S120), maintaining pressure in the processing space (e.g., for a period of time subsequently to pressurizing the processing space) (S130), depressurizing the processing space (e.g., subsequently to maintaining the pressure in the processing space) (S140), and removing the substrate from the chamber (S150). Pressurizing the processing space (S120) may include supplying fluid at a first flow rate (S122), supplying fluid at a second flow rate (S124), and supplying fluid at a third flow rate (S126). Depressurizing the processing space (S140) may include discharging the fluid at a fourth flow rate (S142) and discharging the fluid at a fifth flow rate (S144). Operations S120 to S140 may be a drying process using a supercritical fluid.

Referring to FIGS. 5, 7, and 8, supplying an organic solvent 1 onto the substrate W (S100) may be performed in a chamber different from the chamber 110 in which the drying process is performed. For example, supplying the organic solvent 1 on the substrate W (S100) may be performed in a cleaning chamber. Fine patterns P may be formed on the substrate W, and the organic solvent 1 may fill the space between the patterns P and cover the substrate W. The patterns P may be ultra-high aspect ratio patterns having stiffness of about 3 dyne/cm or less.

Thereafter, the substrate W may be transferred to the processing space 102 of the chamber 110 (S110). As described above, the chamber 110 may be a supercritical processing chamber in which a drying process using a supercritical fluid is performed. The substrate W may be disposed on the substrate supporter 140 within the processing space 102.

FIG. 6 illustrates changes in pressure in the processing space 102 over time in the process of pressurizing the processing space 102 (S120), maintaining the pressure in the processing space 102 (S130), and depressurizing the processing space 102 (S140). In some example embodiments, and as shown in FIG. 6, the pressurizing the processing space of the chamber (S120) may include causing the pressure in the processing space to increase at separate, respective pressure increase rates in a first pressurization period (0 to t1), a second pressurization period (t1 to t2), and a third pressurization period (t2 to t3) that are successive (e.g., sequential periods of time such that the second pressurization period is directly between the first and third pressurization periods, such that the first and second pressurization periods are directly chronologically adjacent and the second and third pressurization periods are directly chronologically adjacent, etc.). For example, as shown in FIG. 6, the first to third pressurization periods may be successive such that the second pressurization period starts at a same time that the first pressurization period ends, t1, and the third pressurization period starts at a same time that the second pressurization period ends, t2.

Referring to FIGS. 5 and 6, in a first pressurization period 0 to t1, fluid may be supplied to the processing space 102 at a first flow rate (S122), which may cause the pressure in the processing space to increase at a first pressure increase rate in the first pressurization period 0 to t1. When the fluid is supplied at the first flow rate, the pressure within the processing space 102 may be less than a critical pressure Pc at which the fluid is supercritical. For example, as shown in FIG. 6, the pressure within the processing space may increase in the first pressurization period 0 to t1 to a first pressure P1 that is smaller than the fluid critical pressure Pc, based on the fluid being supplied into the processing space at the first flow rate in the first pressurization period 0 to t1. As described above, when the fluid is carbon dioxide (CO₂), the critical pressure of carbon dioxide (CO₂) may be about 73.8 bar. A pressure increase rate in the first pressurization period 0 to t1 (which may be referred to as a first pressure increase rate) may be about 1 Bar/s to about 2.5 Bar/s. The first pressure increase rate may be a fixed or substantially fixed pressure increase rate, such that the pressure in the processing space increases at a linear or substantially linear rate in the first pressurization period. If the first flow rate is too low (e.g., such that the first pressure increase rate is less than about 1 Bar/s), the process may be delayed, and if the first flow rate is too high (e.g., such that the first pressure increase rate is greater than about 2.5 Bar/s), the fluid flowing into the processing space may generate vortices or turbulence in the organic solvent. Therefore, there is a risk of causing defects in the pattern P on the substrate W.

Referring further to FIG. 4, when the fluid is supplied at the first flow rate (e.g., in the first pressurization period, such that the pressure in the processing space increases at the first pressure increase rate), the organic solvent 1 and the fluid 2 may be in a state corresponding to region B. That is, the organic solvent 1 may be in a liquid state, and the fluid 2 may be in a gaseous state.

For example, referring further to FIG. 9, the fluid 2 supplied to the processing space 102 in the first pressurization period 0 to t1 in FIG. 6) may cover the organic solvent 1. The gaseous fluid 2 may not be mixed with the organic solvent 1, and the patterns P on the substrate W may be covered by the organic solvent 1, without being exposed to the fluid 2.

Referring to FIGS. 5 and 6, in a second pressurization period t1 to t2, fluid may be supplied to the processing space 102 at a second flow rate (S124), which may cause the pressure in the processing space to increase at a second pressure increase rate in the second pressurization period t1 to t2. When the fluid is supplied at the second flow rate, the pressure within the processing space 102 may exceed the critical pressure Pc. For example, at the beginning of the second pressurization period t1 to t2 (e.g., at t1), the pressure within the processing space 102 may be less than the critical pressure Pc (e.g., may be at the first pressure P1 shown in FIG. 6), but the pressure may continue to increase and exceed the critical pressure Pc. For example, as shown in FIG. 6, the pressure within the processing space may increase in the second pressurization period t1 to t2 from the first pressure P1 that is smaller than the fluid critical pressure Pc to a second pressure P2 that is greater than the critical pressure Pc, based on the fluid being supplied into the processing space at the second flow rate in the second pressurization period t1 to t2. The pressure increase rate in the second pressurization period t1 to t2 (which may be referred to as a second pressure increase rate) may be about 2.5 Bar/s to about 3.5 Bar/s. As shown in at least FIG. 6, the second pressure increase rate may be variable over time in the second pressurization period t1 to t2, such that the pressure in the processing space may increase at a non-linear rate in the second pressurization period t1 to t2.

Referring further to FIG. 4, when the fluid is supplied at the second flow rate, the organic solvent 1 and the fluid 2 may be in a state corresponding to region D. That is, the organic solvent 1 may be in a liquid state, and the fluid 2 may be in a supercritical state.

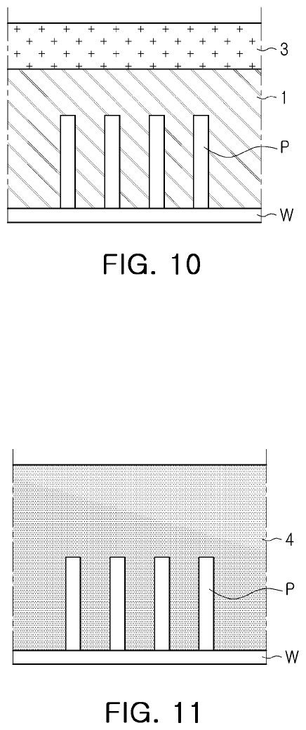

For example, referring further to FIG. 10, the fluid 2 supplied to the processing space 102 in the second pressurization period t1 to t2 may exceed the critical pressure Pc and enter a supercritical state to become fluid 3 in the supercritical state. The fluid 3 in the supercritical state may not be mixed with the organic solvent 1, and the patterns P on the substrate W may be covered by the organic solvent 1, without being exposed to the fluid 3.

Referring to FIGS. 5 and 6, in a third pressurization period t2 to t3, fluid may be supplied at a third flow rate to the processing space 102 (S126) which may cause the pressure in the processing space to increase at a third pressure increase rate in the third pressurization period t1 to t2. When the fluid is supplied at the third flow rate, the pressure within the processing space 102 may be greater than the fluid critical pressure Pc. For example, as shown in FIG. 6, the pressure within the processing space may increase in the third pressurization period t2 to t3 from the second pressure P2 that is greater than the fluid critical pressure Pc to a pressure Pm (referred to herein interchangeably as the third pressure, the maintained pressure, or the like) that is greater than the critical pressure Pc and is further greater than the second pressure P2, based on the fluid being supplied into the processing space at the third flow rate in the third pressurization period t2 to t3. Such a pressure Pm may be a pressure that is equal to or greater than about 73.8 Bar and the fluid that is maintained at the pressure Pm may also be at a temperature that is equal to or greater than about 31° C. A pressure increase rate in the third pressurization period t2 to t3 (which may be referred to as a third pressure increase rate) may be about 0.5 Bar/s to about 2 Bar/s. The third pressure increase rate may be a fixed or substantially fixed pressure increase rate, such that the pressure in the processing space increases at a linear or substantially linear rate in the third pressurization period. As shown the second pressure increase rate in the second pressurization period t1 to t2 may be time-variable such that at least a particular magnitude of the second pressure increase rate in the second pressurization period t1 to t2 (e.g., a maximum second pressure increase rate), which may be a pressure increase rate during a limited portion of the second pressurization period, may be greater than the third pressure increase rate, greater than the first pressure increase rate, or greater than both the first and third pressure increase rates. As shown in FIG. 6, the second pressure increase rate may vary in the second pressurization period t1 to t2 from a pressure increase rate that is equal or substantially equal to the first pressure increase rate to a maximum second pressure increase rate that is greater than both the first and third pressure increase rates and further to a pressure increase rate that is equal or substantially equal to the third pressure increase rate.

Referring further to FIG. 4, when the fluid is supplied at the third flow rate, the organic solvent 1 and the fluid 3 may be in a state corresponding to region E. That is, the organic solvent 1 and the fluid 3 may be in a supercritical state and may be mixed with each other to form a mixed phase.

For example, referring further to FIG. 11, the fluid 3 in a supercritical state may begin to be mixed with the organic solvent 1 in a supercritical state to form a mixed fluid 4. The mixed fluid 4 may cover the substrate W and the patterns P, such that the patterns P may be exposed to (e.g., directly exposed to, in contact with, etc.) the mixed fluid 4.

If the third flow rate is too low (e.g., such that the third pressure increase rate is less than about 0.5 Bar/s), the process may be delayed, and if the third flow rate is too high (e.g., such that the third pressure increase rate is greater than about 2 Bar/s), the fluid flowing into the processing space may generate vortices or turbulence in the mixed fluid 4. Therefore, there is a risk of causing defects in the pattern P on the substrate W.

Referring to FIGS. 5 and 6, in a holding period (t3 to t4), the pressure in the processing space may be maintained (S130) subsequently to pressurizing the processing space at S120. For example the pressure in the processing space may be maintained at a particular fixed pressure magnitude Pm or substantially a particular fixed pressure magnitude Pm that is greater than the fluid critical pressure Pc (and is also greater than the first and second pressures P1 and P2) for a period of time (e.g., the holding period t3 to t4). The processing space 102 may be sealed in the holding period t3 to t4. For example, no fluid may flow into the processing space 102 and no fluid or organic solvent may be discharged from the processing space 102 (e.g., based on each of valves V1, V2a, V2b, V2c, and V3 being in a fully closed position). The holding period t3 to t4 (e.g., the maintaining pressure in the processing space) may be performed to ensure that the fluid and organic solvent in a supercritical state are completely mixed (e.g., as mixed fluid 4 shown in FIG. 11). The pressure Pm within the processing space 102 in the holding period t3 to t4 may be about 130 Bar to about 180 Bar, and the holding period t3 to t4 may last for about 10 seconds to about 60 seconds. For example, the step of maintaining the pressure at S130 may include maintaining the pressure in the processing space of the chamber at about 130 Bar to about 180 Bar during some or all of the holding period t3 to t4. For example, the period of time for which the pressure in the processing space is maintained at S130 (e.g., the length or magnitude of t3 to t4) may be about 10 seconds to about 60 seconds.

For example, as illustrated in FIG. 7, the organic solvent 1 may be formed relatively thick in the center region CR of the substrate W, and the organic solvent 1 may be formed relatively thin in the edge region ER of the substrate W. Time required for the organic solvent 1 and the fluid in a supercritical state to mix may be relatively longer in the center region CR than in the edge region CR. When the fluid and organic solvent 1 are discharged without the holding period t3 to t4, the pattern P in the center region CR may be damaged or collapsed due to surface tension of the organic solvent 1. However, in some example embodiments of the present inventive concepts, the method of processing a substrate includes maintaining the pressure in the processing space (S130), thereby preventing damage or collapse of the pattern P in the center region CR, or reducing or minimizing such damage.

Referring to FIGS. 5-6, the processing space may be depressurized subsequently to maintaining the pressure in the processing space (S140). As shown, the depressurizing the processing space at S140 may include depressurizing the processing space, and thus causing the pressure in the processing space to decrease (e.g., be reduced) at separate, respective pressure reduction rates, in each of a first depressurization period (S142) and a second depressurization period (S144) that are successive (e.g., sequential periods of time such that the first and second depressurization periods are directly chronologically adjacent). For example, as shown in FIG. 6, the first and second depressurization periods may be successive such that the second depressurization period starts at a same time that the first depressurization period ends, t5. Referring to FIGS. 5 and 6, in a first depressurization period t4 to t5, fluid (e.g., the fluid that is separate from the organic solvent and is supplied into the processing space at S120, the mixed fluid, etc.) may be discharged from the processing space 102 at a fourth flow rate (S142). When the fluid is discharged at the fourth flow rate, the pressure within the processing space 102 may be maintained above the fluid critical pressure Pc. For example, as shown in FIG. 6, the pressure within the processing space 102 may decrease in the first depressurization period t4 to t5 from the maintained pressure Pm to a reduced pressure Pr that is smaller than the maintained pressure Pm and is greater than the fluid critical pressure Pc. When the fluid is discharged at the fourth flow rate, the organic solvent mixed with the fluid in the holding period t3 to t4 may also be discharged from the processing space 102, such that the reducing of the pressure in the processing space in the first depressurization period t4 to t5 includes discharging a mixture of the fluid and the organic solvent as a mixed fluid. The first depressurization period t4 to t5 may be performed until the organic solvent is sufficiently discharged from the processing space 102.

Referring to FIGS. 5 and 6, in a second depressurization period t5 to t6, fluid (e.g., the fluid alone or together with the organic solvent as a mixed fluid) may be discharged from the processing space 102 at a fifth flow rate (S144), and the drying process may be completed. When the fluid is discharged at the fifth flow rate, the pressure within the processing space 102 may become less than the critical pressure Pc. For example, at the beginning of the second depressurization period t5 to t6 (e.g., at t5), the pressure within the processing space 102 may be the reduced pressure Pr that is greater than the critical pressure Pc, but the pressure may continue to decrease in the second depressurization period t5 to t6 and become less than the critical pressure Pc (e.g., decrease to a depleted pressure Pn that is smaller than the critical pressure Pc at t6 as shown in FIG. 6). As shown, the pressure may be caused to decrease (e.g., may be reduced) at a non-linear rate in the first depressurization period t4 to t5 and at a linear or substantially linear rate in the second depressurization period t5 to t6.

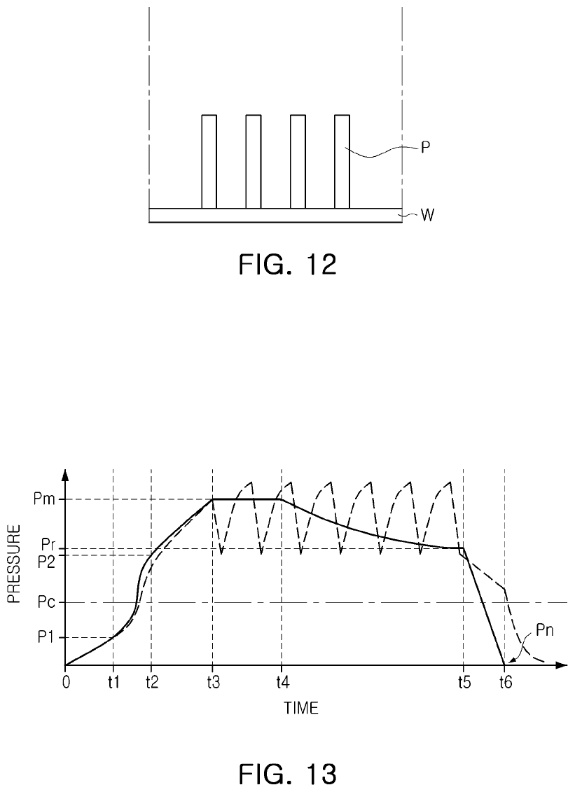

For example, referring further to FIG. 12, in the second depressurization period t5 to t6, the fluid and organic solvent in the processing space 102 may be completely discharged and the pattern P on the substrate W may be exposed.

Referring to FIG. 5, after the drying process is completed, the substrate W may be carried out of the chamber 110 (S150).

Throughout some or all of the operations S100 to S150 of the method shown in FIG. 5, one or more heaters 205, 180, etc. may be operated to generate heat to cause the temperature in the processing space 102 to be greater than a critical temperature of the fluid, such that in the third pressurization period (t2 to t3), the holding period (t3 to t4), and the first depressurization period (t4 to t5) the fluid and/or mixed fluid is at both a pressure that is greater than the critical pressure of the fluid and a temperature that is greater than the critical temperature of the fluid, such that the fluid is in a supercritical state (e.g., a pressure that is greater than about 73.8 Bar and a temperature that is greater than about 31° C., when the fluid is carbon dioxide (CO₂)).

Hereinafter, the operation of the substrate processing device 100 in the drying process is described with reference to FIGS. 2 and 3.

In some example embodiments, in the process (S120) of pressurizing the processing space 102, fluid may be supplied to the lower supply port 134 of the chamber 110 through the lower supply line 172 (e.g., exclusively of the upper supply line 170, such that fluid is not supplied to the upper supply port 124 in the process (S120) of pressurizing the processing space 102). Since fluid is not supplied to the upper supply port 124 in the process (S120) of pressurizing the processing space 102, fluid may be prevented from directly flowing into (e.g., onto) the upper surface of the substrate W based on flowing normally to the upper surface of the substrate W and downwards towards the substrate W via the upper supply port 124. In addition, since the blocking member 160 is disposed on the lower supply port 134, fluid ending the processing space via the lower supply port 134 may be prevented from directly flowing into the lower surface of the substrate W. Therefore, it is possible to prevent the pattern P from being tilted or collapsed due to the pressure of the fluid at the initial stage of pressurization, or reduce or minimize a risk of such tilting or collapsing, based on pressurizing the processing space 102 via supplying fluid into the processing space through the lower supply port 134 and not supplying any fluid into the processing space 102 through the upper supply port 124 during such process (S120). In the process (S120) of pressurizing the processing space 102, the upper valve V1 may be closed, and in some example embodiments, the discharge valve V3 may also be closed.

In some example embodiments, different lower valves V2a, V2b, and V2c may be used in the first pressurization period 0 to t1, the second pressurization period t1 to t2, and the third pressurization period t2 to t3 to control the flow rate of fluid into the processing space 102 via the lower supply port 134. For example, in the first pressurization period 0 to t1, only the first lower valve V2a may be opened, and the first lower valve V2a may be controlled so that fluid is supplied to the processing space 102 at the first flow rate. In the second pressurization period t1 to t2, only the second lower valve V2b may be opened, and the second lower valve V2b may be controlled so that fluid is supplied to the processing space 102 at the second flow rate. In the third pressurization period t2 to t3, only the third lower valve V2c may be opened, and the third lower valve V2c may be controlled so that fluid is supplied to the processing space 102 at the third flow rate.

In the process (S130) of maintaining pressure in the processing space (S130), the upper supply line 170, lower supply line 172, and lower discharge line 174 may all be closed. For example, the upper valve V1, the lower valves V2a, V2b, and V2c, and the discharge valve V3 may all be closed. Fluid may not flow into the processing space 102, and thus, no fluid or organic solvent may be discharged from the processing space 102.

In the first depressurization period t4 to t5, fluid may be supplied to the upper supply port 124 of the chamber 110 through the upper supply line 170, and fluid and an organic solvent may be discharged through the discharge line 174 below the chamber 110 (e.g., as a mixed fluid). When the organic solvent is discharged, fluid is supplied to the upper supply port 124 so that flow may occur from the upper supply port 124 through the processing space 102 to the lower supply port 134. Accordingly, the flow of fluid and organic solvent within the processing space 102 may be smoothened, and thus, the organic solvent may be discharged more efficiently.

In the first depressurization period t4 to t5, the fluid may be discharged through the lower discharge line 174 and simultaneously supplied to the processing space 102 through the upper supply line 170. For example, in the first depressurization period t4 to t5, additional fluid (e.g., “fresh” fluid) may be supplied into the processing space 102 through the upper supply port 124 while simultaneously fluid, and potentially also organic solvent, may be discharged from the processing space 102 through the lower supply port 134. Accordingly, the pressure in the processing space 102 may be maintained higher than the critical pressure Pc in the first depressurization period t4 to t5 based on supplying additional fluid to at least partially offset a reduction in pressure due to the discharge of fluid (alone or together with organic solvent) from the processing space 102 via the lower supply port 134, such that the pressure in the processing space 102 reduces more slowly, and thus remains greater, than if the pressure were reduced based on discharging fluid from the processing space 102 without simultaneously supplying additional fluid into the processing space 102. Therefore, it is possible to maintain the supercritical state of the fluid in the processing space 102 (e.g., cause the pressure to be reduced to a reduced pressure Pr that is still greater than the critical pressure Pc), while the organic solvent is being discharged, and prevent the organic solvent from remaining between the patterns P on the substrate W or the patterns P from being collapsed by the organic solvent. As a result, the reliability of a semiconductor device manufactured based on such substrate and the patterns thereon may be improved based on processing the substrate according to the method of some example embodiments due to reduced process defects caused by residual organic solvent remaining between the patterns P and/or reduced process defects caused by tilted and/or collapsed patterns P on the substrate W.

In addition, since the fluid supplied to the upper supply port 124 is supplied onto the center region CR of the substrate W, the organic solvent on the substrate W may be pushed from the center region CR to the edge region ER to be discharged. Therefore, it is possible to prevent cluster defects from occurring due to local concentration of the organic solvent on the surface of the substrate, or reduce or minimize such defects. As a result, the reliability of a semiconductor device manufactured based on such substrate and the patterns thereon may be improved based on processing the substrate according to the method of some example embodiments due to reduced process defects such as the aforementioned cluster defects.

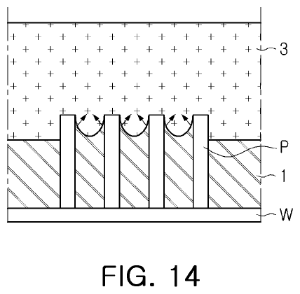

FIG. 13 illustrates pressure changes over time in a processing space within a chamber according to some example embodiments of the present inventive concepts and a comparative example. In FIG. 13, the solid line graph represents a pressure change according to some example embodiments of the present inventive concepts illustrated in FIG. 6, and the dotted line graph represents a pressure change according to the comparative example. FIG. 14 is a schematic diagram illustrating a drying process according to the comparative example.

Referring to FIGS. 13 and 14, a pressure increase rate according to some example embodiments of the present inventive concepts in the second pressurization period t1 to t2 may be greater than a pressure increase rate in the same time period t1 to t2 according to the comparative example.

In the comparative example, fluid may be supplied into the processing space such that the fluid 3 reaches a supercritical state prior to mixing or substantial mixing with the organic solvent 1, such that the fluid 3 in a supercritical state is caused to mix (e.g., mix slowly) with the organic solvent 1. In the comparative example, when the fluid 3 in a supercritical state is slowly mixed with the organic solvent 1, surface tension may act on the patterns P at the interface between the fluid 3 and the organic solvent 1. Accordingly, the patterns P may be tilted or collapsed. In addition, the organic solvent 1 may include particles generated during the cleaning process, and thus, when the supercritical fluid 3 is slowly mixed with the organic solvent 1, particles may precipitate.

In contrast, in some example embodiments of the present inventive concepts, the second flow rate in the second pressurization period t1 to t2 may be greater than both the first flow rate in the first pressurization period 0 to t1 and the third flow rate in the third pressurization period t2 to t3. For example, the pressure increase rate in the second pressurization period t1 to t2 (e.g., the second pressure increase rate, the maximum second pressure increase rate, etc.) may be greater than the pressure increase rate in the first pressurization period 0 to t1 (e.g., the first pressure increase rate) and the pressure increase rate in the third pressurization period t2 to t3 (e.g., the third pressure increase rate). Therefore, the fluid 3 is rapidly mixed with the organic solvent 1 in the second pressurization period t1 to t2 exceeding the critical pressure Pc based on the greater pressure increase rate in the second pressurization period t1 to t2 during which the pressure increases from a first pressure P1 that is smaller than the critical pressure Pc to a second pressure P2 that is greater than the critical pressure Pc, thereby preventing the patterns P from being tilted or collapsed (or reducing or minimizing such tilting and/or collapsing) and preventing particles from precipitating (or reducing or minimizing such precipitation).

In addition, unlike the comparative example, the method of processing a substrate according to some example embodiments of the present inventive concepts may include the holding period t3 to t4 (e.g., during which the pressure in the processing space is maintained at a particular, fixed pressure Pm that is greater than the critical pressure Pc). As described above, since the fluid 3 may be sufficiently mixed with the organic solvent 1 in the holding period t3 to t4, the organic solvent 1 may be entirely substituted with the fluid 3 even in the center region CR, as well as in the edge region ER, of the substrate W. Accordingly, defects of the pattern P in the center region CR may be reduced, minimized, or prevented due to such entire substitution of organic solvent 1 with the fluid 3, such that the organic solvent may be entirely removed from contact with the patterns P and may be entirely removed from the processing space based on depressurizing the processing space via discharge of the fluid from the processing space.

Next, a method of manufacturing a semiconductor device including a method of processing a substrate is described. The method of manufacturing a semiconductor device according to some example embodiments may include forming a pattern P on a substrate W, performing a cleaning process on the substrate W, transferring the substrate W to the processing space 102 of the chamber 110, performing a drying process on the substrate W within the chamber 110, and removing the substrate W from the chamber 110.

In some example embodiments, the pattern P may be a trench pattern formed by etching the upper surface of the substrate W. For example, the trench patterns may include a semiconductor material, such as silicon, may be a pattern having an ultra-high aspect ratio, and may have stiffness of about 3 dyne/cm or less. In some example embodiments, the pattern P may be formed by depositing a conductive material or an insulating material on the substrate W and performing etching.

Performing the cleaning process may include performing a chemical process, a rinse process, and an organic solvent supply process on the substrate W. Unnecessary patterns on the substrate W may be removed through the chemical process, and foreign substances etched by the chemical process may be diluted with an organic solvent through the rinse process and the organic solvent supply process.

According to some example embodiments of the present inventive concepts, since fluid is rapidly mixed with the organic solvent in the second pressurization period exceeding the critical pressure, the patterns on the substrate may be prevented from tilting or collapsing (or such tilting or collapsing may be reduced or minimized) and particles may be prevented from precipitating (or such precipitation may be reduced or minimized). As a result, the reliability of a semiconductor device manufactured based on such substrate and the patterns thereon may be improved based on processing the substrate according to the method of some example embodiments due to reduced process defects caused by tilted and/or collapsed patterns P on the substrate W and/or precipitated particles on the patterns P.

In addition, since the method of processing a substrate includes the process of maintaining pressure so that the fluid and the organic solvent are sufficiently mixed, the patterns on the substrate may be prevented from being collapsed by the organic solvent in the process of discharging the fluid (or such collapsing may be reduced or minimized). As a result, the reliability of a semiconductor device manufactured based on such substrate and the patterns thereon may be improved based on processing the substrate according to the method of some example embodiments due to reduced process defects caused by residual organic solvent remaining between the patterns P and/or reduced process defects caused by tilted and/or collapsed patterns P on the substrate W.

While some example embodiments have been illustrated and described above, it will be apparent to those skilled in the art that modifications and variations could be made without departing from the scope of the present inventive concepts as defined by the appended claims.

What is claimed is:

1. A method of processing a substrate, the method comprising:
supplying an organic solvent to the substrate;
transferring the substrate to a processing space in a chamber;
supplying fluid to the processing space of the chamber and pressurizing the processing space;
maintaining pressure in the processing space of the chamber for a period of time subsequently to pressurizing the processing space; and
depressurizing the processing space of the chamber subsequently to maintaining the pressure in the processing space,
wherein the pressurizing the processing space of the chamber includes causing the pressure in the processing space to increase in each of a first pressurization period, a second pressurization period, and a third pressurization period that are successive, and
wherein a pressure increase rate in the second pressurization period is greater than a pressure increase rate in the third pressurization period.

2. The method of claim 1, wherein the pressure increase rate in the second pressurization period is greater than a pressure increase rate in the first pressurization period.

3. The method of claim 1, wherein a pressure increase rate in the first pressurization period is 1 Bar/s to 2.5 Bar/s.

4. The method of claim 1, wherein the pressure increase rate in the second pressurization period is 2.5 Bar/s to 3.5 Bar/s.

5. The method of claim 1, wherein the pressure increase rate in the third pressurization period is 0.5 Bar/s to 2 Bar/s.

6. The method of claim 1, wherein when the maintaining the pressure in the processing space maintains the pressure in the processing space of the chamber at 130 Bar to 180 Bar.

7. The method of claim 1, wherein the period of time for which the pressure in the processing space of the chamber is maintained is 10 seconds to 60 seconds.

8. The method of claim 1, wherein the pressure in the processing space in the first pressurization period is lower than a critical pressure of the fluid.

9. The method of claim 1, wherein the pressure in the processing space in the second pressurization period is higher than a critical pressure of the fluid.

10. The method of claim 1, wherein the pressure in the processing space in the third pressurization period is maintained to be higher than a critical pressure of the fluid.

11. The method of claim 1, wherein, the depressurizing the processing space includes causing both the organic solvent and the fluid to be discharged from the processing space of the chamber.

12. The method of claim 1, wherein
the depressurizing the processing space includes causing the pressure in the processing space to decrease in each of a first depressurization period and a second depressurization period that are successive, and
a pressure reduction rate in the second depressurization period is greater than a pressure reduction rate in the first depressurization period.

13. The method of claim 12, wherein, in the first depressurization period, the pressure in the processing space is maintained to be higher than a critical pressure of the fluid.

14. The method of claim 12, wherein the depressurizing the processing space includes supplying the fluid to the processing space in the first depressurization period.

15. A method of processing a substrate, the method comprising:
pressurizing a processing space of a chamber in which the substrate is located based on supplying fluid to a lower portion of the substrate in the processing space of the chamber through a lower supply line;
maintaining pressure in the processing space of the chamber for a period of time subsequently to pressurizing the processing space; and
depressurizing the processing space subsequently to maintaining the pressure in the processing space based on discharging the fluid through a lower discharge line,
wherein the pressurizing the processing space includes causing the pressure in the processing space to increase in each of a first pressurization period, a second pressurization period, and a third pressurization period that are successive,
wherein a pressure increase rate in the second pressurization period is greater than a pressure increase rate in the third pressurization period,
wherein the depressurizing the processing space includes causing the pressure in the processing space to decrease in each of a first depressurization period and a second depressurization period, and
wherein the depressurizing the processing space includes supplying additional fluid to the processing space of the chamber through an upper supply line in the first depressurization period.

16. The method of claim 15, wherein
the lower supply line is connected to a first lower valve, a second lower valve, and a third lower valve in parallel, and
the depressurizing the processing space includes opening the first lower valve in the first pressurization period, opening the second lower valve in the second pressurization period, and opening the third lower valve in the third pressurization period.

17. The method of claim 15, wherein the maintaining the pressure in the processing space of the chamber includes closing each of the lower supply line, the upper supply line, and the lower discharge line.

18. The method of claim 15, wherein, in the second depressurization period, the additional fluid is not supplied to the processing space of the chamber through the upper supply line.

19. The method of claim 15, wherein a pressure reduction rate at which the pressure in the processing space is decreased in the second depressurization period is greater than a pressure reduction rate at which the pressure in the processing space is decreased in the first depressurization period.

20. A method of manufacturing a semiconductor device, the method comprising:
forming a pattern on a substrate;
performing a cleaning process on the substrate;
transferring the substrate to a processing space in a chamber;
performing a drying process on the substrate within the chamber; and
removing the substrate from the chamber,
wherein the cleaning process includes supplying an organic solvent to the substrate,
wherein the drying process includes
supplying fluid to the processing space of the chamber and pressurizing the processing space,
maintaining pressure in the processing space of the chamber for a period of time subsequently to pressurizing the processing space, and
depressurizing the processing space of the chamber subsequently to maintaining the pressure in the processing space, and
wherein the pressurizing the processing space of the chamber includes causing the pressure in the processing space to increase in each of a first pressurization period, a second pressurization period, and a third pressurization period that are successive,
wherein a pressure increase rate in the second pressurization period is greater than a pressure increase rate in the third pressurization period,
wherein the pressurizing the processing space includes supplying the fluid to a lower portion of the substrate through a lower supply line,
wherein a temperature of the fluid supplied to the processing space is 40° C. to 90° C., and
wherein the fluid includes at least one of carbon dioxide (CO₂), nitrogen (N₂), nitrous oxide (N₂O), hexafluoroethane (C₂F₆), or sulfur hexafluoride (SF₆).
